(19) United States
(12) Patent Application Publication
(10) Pub. No.: US 2026/0362618 A1
(43) Pub. Date: Nov. 12, 2026

(54) DISPLAY APPARATUS AND ELECTRONIC DEVICE

(71) Applicant: SHANGHAI TIANMA MICROELECTRONICS CO., LTD., Shanghai (CN)

(72) Inventors: Shouzheng WU, Shanghai (CN); Xiao LI, Shanghai (CN); Wen GAO, Shanghai (CN); Yongxin HE, Shanghai (CN); Zhenyu JIA, Shanghai (CN); Yongfeng LIU, Shanghai (CN)

(73) Assignee: SHANGHAI TIANMA MICROELECTRONICS CO., LTD., Shanghai (CN)

(21) Appl. No.: 19/724,968

(22) Filed: Jun. 30, 2026

(30) Foreign Application Priority Data
Feb. 28, 2026 (CN) 202610244069.1

(51) Int. Cl. H05K 5/02; H05K 5/04

(52) U.S. Cl. CPC H05K 5/0247; H05K 5/04

(57) ABSTRACT

A display apparatus and an electronic device, relating to the field of display devices. The display apparatus includes: a support frame including a first surface and second surface opposite to each other; a display module fixed to the first surface via an electrically debondable adhesive layer; a circuit board positioned on a side of the support frame facing away from the display module; a conductive element positioned between the display module and the circuit board, the conductive element being electrically connected to the electrically debondable adhesive layer; and a first conductive connector, where the circuit board and the conductive element are electrically connected via the first conductive connector, the first conductive connector abuts against at least one of the circuit board or the conductive element, and the circuit board provides a predetermined voltage for the electrically debondable adhesive layer via the first conductive connector.

This application claims the priority to Chinese Patent Application No.202610244069.1, titled “DISPLAY APPARATUS AND ELECTRONIC DEVICE”, filed on Feb. 28, 2026 with the China National Intellectual Property Administration, which is incorporated herein by reference in its entirety.

### FIELD

The present disclosure relates to the field of display devices, and in particular, to a display apparatus and an electronic device.

### BACKGROUND

With the continuous advancement of science and technology, an increasing number of electronic devices having a display function have been widely used in daily life and work of people, bringing great convenience to daily life and work. The main structure for an electronic device to realize the display function is a display apparatus.

Generally, a display apparatus of an electronic device includes a display module and a support frame. In a conventional display apparatus, the display module is typically bonded and fixed to the support frame via an adhesive layer, and the cured adhesive layer makes it inconvenient to detach the display module.

### SUMMARY

In view of the above issues, a display apparatus and an electronic device are provided in the present disclosure.

In an embodiment of the present disclosure, a display apparatus is provided. The display apparatus includes:

a support frame including a first surface and a second surface opposite to each other;

a display module fixed to the first surface via an electrically debondable adhesive layer;

a circuit board positioned on a side of the support frame facing away from the display module;

a conductive element positioned between the display module and the circuit board, the conductive element being electrically connected to the electrically debondable adhesive layer; and

a first conductive connector, where the circuit board and the conductive element are electrically connected to each other via the first conductive connector, the first conductive connector abuts against at least one of the circuit board or the conductive element, and the circuit board is configured to provide a predetermined voltage for the electrically debondable adhesive layer via the first conductive connector.

In an embodiment of the present disclosure, an electronic device is further provided. The electronic device includes the above display apparatus. The display apparatus includes:

a support frame including a first surface and a second surface opposite to each other;

a display module fixed to the first surface via an electrically debondable adhesive layer;

a circuit board positioned on a side of the support frame facing away from the display module;

a conductive element positioned between the display module and the circuit board, the conductive element being electrically connected to the electrically debondable adhesive layer; and

a first conductive connector, where the circuit board and the conductive element are electrically connected to each other via the first conductive connector, the first conductive connector abuts against at least one of the circuit board or the conductive element, and the circuit board is configured to provide a predetermined voltage for the electrically debondable adhesive layer via the first conductive connector.

### BRIEF DESCRIPTION OF THE DRAWINGS

To more clearly illustrate the embodiments of the present disclosure or in the related art, the drawings required for describing the embodiments or the prior art will be briefly introduced below. Apparently, the drawings in the following description are only embodiments of the present disclosure.

The structures, proportions, sizes, etc., illustrated in the drawings of the specification are only used to cooperate with the contents disclosed in the specification, to understand and read, and are not intended to limit the practical limiting conditions of the present disclosure, so they do not have technical substantive significance. Any structural modification, change of proportion relations, or adjustment of size, without affecting the effects that are generated and the objectives that are achieved by the present disclosure, should still fall within the scope of the technical contents disclosed in the present disclosure.

FIG. 1 is a schematic structural diagram of a display apparatus provided according to some embodiments of the present disclosure;

FIG. 2 is a schematic structural diagram of a display apparatus provided according to some embodiments of the present disclosure;

FIG. 3 is a schematic structural diagram of a display apparatus provided according to some embodiments of the present disclosure;

FIG. 4 is a schematic structural diagram of a display apparatus provided according to some embodiments of the present disclosure;

FIG. 5 is a schematic structural diagram of a display apparatus provided according to some embodiments of the present disclosure;

FIG. 6 is a schematic structural diagram of a display apparatus provided according to some embodiments of the present disclosure;

FIG. 7 is a partially enlarged view of a display apparatus in a conductive strip region provided according to some embodiments of the present disclosure;

FIG. 8 is a schematic structural diagram of a display apparatus provided according to some embodiments of the present disclosure;

FIG. 9 is a schematic structural diagram of a display apparatus provided according to some embodiments of the present disclosure;

FIG. 10 is a top view of a display apparatus provided according to some embodiments of the present disclosure;

FIG. 11 is a cross-sectional view of the display apparatus shown in FIG. 10 along a Q-Q′ direction;

FIG. 12 is a top view of a display apparatus provided according to some embodiments of the present disclosure;

FIG. 13 is a cross-sectional view of the display apparatus shown in FIG. 12 along a Q-Q′ direction;

FIG. 14 is a top view of a display apparatus provided according to some embodiments of the present disclosure;

FIG. 15 is a cross-sectional view of the display apparatus shown in FIG. 14 along a Q-Q′ direction;

FIG. 16 is another cross-sectional view of the display apparatus shown in FIG. 14 along a Q-Q′ direction;

FIG. 17 is a top view of a display apparatus provided according to some embodiments of the present disclosure;

FIG. 18 is a cross-sectional view of the display apparatus shown in FIG. 17 along a Q-Q′ direction;

FIG. 19 is a partial enlarged schematic diagram of a first conductive connector and a conductive element at an abutment position in a display apparatus provided according to some embodiments of the present disclosure; and

FIG. 20 is a schematic structural diagram of an electronic device provided according to some embodiments of the present disclosure.

Reference numerals in the drawings are described as follows:
Support frame 100, first surface 101, second surface 102, display module 103, electrically debondable adhesive layer 104, circuit board 105, conductive element 106, first conductive connector 107, bent portion 108, side surface 109, conductive plate 110, second conductive connector 111, conductive strip 112, second insulating adhesive layer 113, third conductive connector 114, first region 115, second region 116, first insulating adhesive layer 117, groove 118, first portion 119, second portion 120, fourth conductive connector 121, insulating layer 122, conductive layer 123, fifth conductive connector 124, adhesive frame 125, position-limiting groove 126, display apparatus 127, positive terminal N+, negative terminal N−, first preset spacing D1, and second preset spacing D2.

### DETAILED DESCRIPTION

The embodiments of the present disclosure will be clearly and completely described below in conjunction with the accompanying drawings in the embodiments of the present disclosure. It is known that with the development of technology and the emergence of new scenarios, the embodiments provided by the embodiments of the present disclosure are also applicable to similar technical issues.

As described in the background technology, in a conventional display apparatus, a solution of bonding and fixing a display module on a support frame via a common adhesive layer is inconvenient for detachment of the display module.

The inventor found through research that when the display module and the support frame are bonded and fixed to each other via an electrically debondable adhesive layer, a predetermined voltage may be applied to the electrically debondable adhesive layer via a circuit board to control the electrically debondable adhesive to lose adhesion, and the display module can be easily detached, thereby facilitating the detachment operation between the display module and the support frame.

When the display module and the support frame are bonded and fixed using the electrically debondable adhesive layer, if the circuit board is fixed to a surface of the display module facing the support frame, the circuit board is electrically connected to the electrically debondable adhesive layer by welding. When detaching the display module, the circuit structure between the circuit board and the electrically debondable adhesive layer is destructively detached, which is inconvenient for detachment of the circuit board.

In view of this, a display apparatus is provided according to some embodiments of the present disclosure. The display apparatus includes a support frame, a display module, a circuit board, a conductive element and a first conductive connector.

The support frame includes a first surface and a second surface opposite to each other.

The display module is fixed to the first surface via an electrically debondable adhesive layer.

The circuit board is positioned on a side of the support frame facing away from the display module.

The conductive element is positioned between the display module and the circuit board, and the conductive element is electrically connected to the electrically debondable adhesive layer.

The circuit board and the conductive element are electrically connected to each other via the first conductive connector, the first conductive connector abuts against at least one of the circuit board or the conductive element, and the circuit board is configured to provide a predetermined voltage for the electrically debondable adhesive layer via the first conductive connector.

In the embodiments of the present disclosure, the display module and the circuit board are arranged on two opposite sides of the support frame, respectively. The display module and the support frame are bonded and fixed to each other via the electrically debondable adhesive layer, and a predetermined voltage is provided for the electrically debondable adhesive layer via the circuit board to control the electrically debondable adhesive layer to lose adhesion, thereby facilitating detachment of the display module.

Since the circuit board is arranged on the side of the support frame facing away from the display module, it is not required to detach the circuit board while detaching the display module, thereby avoiding the influence of the detachment of the display module on the reliability of the circuit board.

In addition, the electrically debondable adhesive layer is electrically connected to the conductive element, and the circuit board and the conductive element are electrically connected to each other via the first conductive connector, and the circuit board provides the predetermined voltage for the electrically debondable adhesive layer when detaching the display module to control the electrically debondable adhesive layer to lose adhesion. Since the first conductive connector abuts against at least one of the circuit board or the conductive element, after the display module is detached, the abutment force at the abutment position is naturally released, thereby achieving non-destructive separation between the circuit board and the conductive element at the abutment position. Compared with a solution in which the circuit board and the electrically debondable adhesive layer are electrically connected to each other via welding, the embodiments of the present disclosure does not require destructive detachment of the circuit structure between the circuit board and the electrically debondable adhesive layer when detaching the display module, thereby facilitating non-destructive detachment of the circuit structure connected to the circuit board.

To make the above objects, features, and advantages of the present disclosure more apparent and understandable, the present disclosure will be described in further detail below in conjunction with the accompanying drawings and specific embodiments.

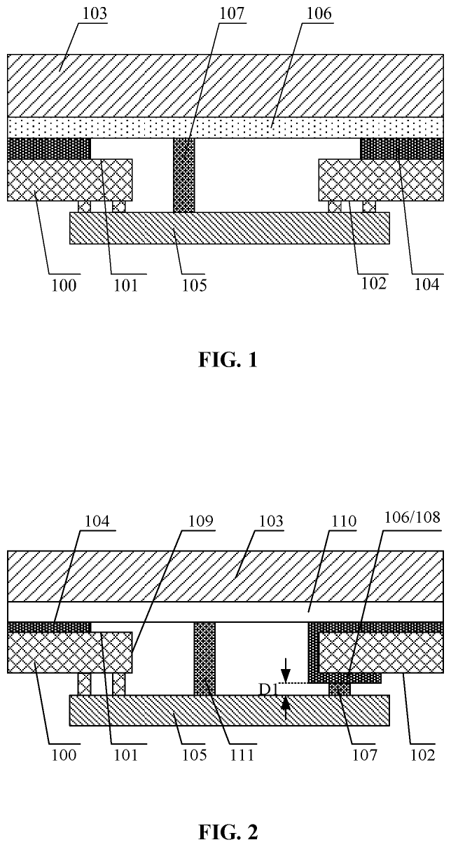

Referring to FIG. 1, FIG. 1 is a schematic structural diagram of a display apparatus provided according to some embodiments of the present disclosure, and the display apparatus includes a support frame 100, a display module 103, a circuit board 105, a conductive element 106 and a first conductive connector 107.

The support frame 100 includes a first surface 101 and a second surface 102 opposite to each other.

The display module 103 is fixed to the first surface 101 via an electrically debondable adhesive layer 104.

The circuit board 105 is positioned on a side of the support frame 100 facing away from the display module 103.

The conductive element 106 is positioned between the display module 103 and the circuit board 105, and the conductive element 106 is electrically connected to the electrically debondable adhesive layer 104.

The circuit board 105 and the conductive element 106 are electrically connected to each other via the first conductive connector 107, the first conductive connector 107 abuts against at least one of the circuit board 105 or the conductive element 106, and the circuit board 105 is configured to provide a predetermined voltage for the electrically debondable adhesive layer 104 via the first conductive connector 107.

The circuit board 105 may be fixed to the second surface 102 by means of screws or snap-fit devices, etc.

In some embodiments, a lower end of the first conductive connector 107 may be fixed to the circuit board 105, and an upper end of the first conductive connector 107 is a free end and abuts against the conductive element 106. In this embodiment, after the display module 103 is bonded and fixed to the first surface 101 via the electrically debondable adhesive layer 104, with the display module 103 bonded and fixed to the support frame 100, the conductive element 106 applies a pressing force to the upper end of the first conductive connector 107, and the conductive element 106 abuts against the upper end of the first conductive connector 107. After the display module 103 is detached, the pressing force is released, and the conductive element 106 is separated from the upper end of the first conductive connector 107.

In some embodiments, the upper end of the first conductive connector 107 is fixed to the conductive element 106, and the lower end of the first conductive connector 107 is a free end and abuts against the circuit board 105. In this embodiment, after the display module 103 is bonded and fixed to the first surface 101 via the electrically debondable adhesive layer 104, the display module 103 bonded and fixed to the support frame 100 presses against the first conductive connector 107, causing the lower end of the first conductive connector 107 to apply a pressing force to the circuit board 105, and the lower end of the first conductive connector 107 abuts against the circuit board 105. After the display module 103 is detached, the pressing force is released, and the lower end of the first conductive connector 107 is separated from the circuit board 105.

In some embodiments, both the upper end and the lower end of the first conductive connector 107 are free ends. When the display module 103 is fixed to the first surface 101 and the circuit board 105 is fixed to the second surface 102, the display module 103 presses against the conductive element 106, causing the conductive element 106 and the circuit board 105 to compress the first conductive connector 107 between the conductive element 106 and the circuit board 105, and the upper end of the first conductive connector 107 abuts against the conductive element 106 and the lower end of the first conductive connector 107 abuts against the circuit board 105. After the display module 103 is detached, the compression force of the conductive element 106 and the circuit board 105 on the first conductive connector 107 is released, and the lower end of the first conductive connector 107 is separated from the circuit board 105, and the upper end of the first conductive connector 107 is separated from the conductive element 106.

If one end of the first conductive connector 107 is fixedly connected to a structural element facing the first conductive connector 107, a screw or welding may be adopted.

In the display apparatus provided in the embodiments of the present disclosure, the display module 103 and the support frame 100 are bonded and fixed to each other via the electrically debondable adhesive layer 104, and the predetermined voltage may be provided for the electrically debondable adhesive layer 104 via the circuit board 105 to cause the electrically debondable adhesive layer 104 to lose adhesion, thereby facilitating detachment of the display module 103.

In addition, since the circuit board 105 and the display module 103 are arranged on two opposite sides of the support frame 100, respectively, it is not required to detach the circuit board 105 when detaching the display module 103, thereby avoiding the influence of the detachment of the display module 103 on the reliability of the circuit board 105.

Moreover, since the first conductive connector 107 abuts against at least one of the circuit board 105 or the conductive element 106, after the display module 103 is detached, as the display module 103 is separated from the support frame 100, the pressing force applied at the abutment position is synchronously released, and the first conductive connector 107 is naturally separated from the structural element facing the first conductive connector 107 at the abutment position, thereby achieving non-destructive separation between the circuit board 105 and the conductive element 106, without destructive detachment of the circuit structure between the circuit board 105 and the electrically debondable adhesive layer 104, thereby facilitating non-destructive detachment of the circuit structure connected to the circuit board 105.

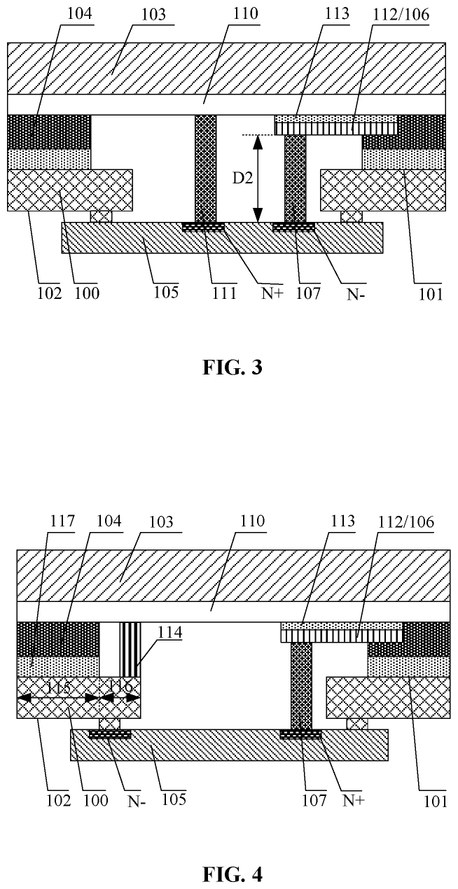

Referring to FIG. 2, FIG. 2 is a schematic structural diagram of a display apparatus provided according to some embodiments of the present disclosure. On the basis of other embodiments, the support frame 100 includes a side surface 109 connecting the first surface 101 and the second surface 102; the electrically debondable adhesive layer 104 includes a bent portion 108, the bent portion 108 extends to the second surface 102 along the side surface 109, and the bent portion 108 partially overlaps the second surface 102; a first preset spacing D1 is provided between a part of the bent portion 108 that overlaps the second surface 102 and the circuit board 105; the conductive element 106 includes the bent portion 108, that is, the bent portion 108 serves as the conductive element 106; and the first conductive connector 107 is positioned between the bent portion 108 and the circuit board 105.

In some embodiments, as shown in FIG. 2, a surface of the display module 103 facing the support frame 100 is provided with a conductive plate 110, which is electrically conductive, and the display module 103 is bonded and fixed to the electrically debondable adhesive layer 104 via the conductive plate 110. A second conductive connector 111 is connected between the circuit board 105 and the conductive plate 110, and the second conductive connector 111 and the first conductive connector 107 are connected to different positions of the electrically debondable adhesive layer 104. In this way, the circuit board 105 applies a predetermined voltage at different positions of the electrically debondable adhesive layer 104 via the second conductive connector 111 and the first conductive connector 107, respectively.

In some embodiments shown in FIG. 2, the electrically debondable adhesive layer 104 is folded onto the second surface 102 based on the bent portion 108, and the first conductive connector 107 is arranged based on the first preset spacing D1 between a part of the bent portion 108 that overlaps the second surface 102 and the circuit board 105, to implement the electrical connection between the circuit board 105 and the electrically debondable adhesive layer 104.

Referring to FIG. 3, FIG. 3 is a schematic structural diagram of a display apparatus provided according to some embodiments of the present disclosure. On the basis of other embodiments, the display apparatus shown in FIG. 3 further includes a conductive strip 112 positioned on a side of the display module 103 facing the support frame 100. The conductive strip 112 is electrically connected to the electrically debondable adhesive layer 104. The conductive element 106 includes the conductive strip 112. A second preset spacing D2 is provided between the conductive strip 112 and the circuit board 105. The first conductive connector 107 is positioned between the conductive strip 112 and the circuit board 105.

In some embodiments, similar to the embodiments shown in FIG. 2, as shown in FIG. 3, a surface of the display module 103 facing the support frame 100 is provided with a conductive plate 110, which is electrically conductive, and the display module 103 is bonded and fixed to the electrically debondable adhesive layer 104 via the conductive plate 110. A second conductive connector 111 is connected between the circuit board 105 and the conductive plate 110, and the second conductive connector 111 and the first conductive connector 107 are connected to different positions of the electrically debondable adhesive layer 104. In this way, the circuit board 105 applies a predetermined voltage at different positions of the electrically debondable adhesive layer 104 via the second conductive connector 111 and the first conductive connector 107, respectively.

In some embodiments shown in FIG. 3, the electrically debondable adhesive layer 104 is electrically connected to the first conductive connector 107 via the conductive strip 112, and the first conductive connector 107 is arranged based on the second preset spacing D2 between the conductive strip 112 and the circuit board 105, to implement the electrical connection between the circuit board 105 and the electrically debondable adhesive layer 104.

In some embodiments, as shown in FIG. 3, a surface of the display module 103 facing away from a display side of the display module 103 is fixed to a conductive plate 110; the conductive plate 110 is fixed to the first surface 101 via the electrically debondable adhesive layer 104 and is electrically connected to the electrically debondable adhesive layer 104; the conductive plate 110 is insulated from the conductive strip 112, for example, a side of the conductive strip 112 facing the conductive plate 110 is provided with an insulating adhesive layer (i.e., a second insulating adhesive layer 113 hereinafter) to insulate the conductive strip 112 from the conductive plate 110. The conductive plate 110 may be a metal plate, or an insulating plate with a conductive layer on its surface, etc.

The circuit board 105 includes a positive terminal N+ and a negative terminal N− that are connected to a power circuit, one of the positive terminal N+ and the negative terminal N− is electrically connected to one end of the first conductive connector 107, and the other of the positive terminal N+ and the negative terminal N− is electrically connected to one end of the second conductive connector 111. Another end of the second conductive connector 111 is electrically connected to the conductive plate 110. The second conductive connector 111 abuts against at least one of the circuit board 105 or the conductive plate 110. The circuit board 105 may apply a predetermined voltage at different positions of the electrically debondable adhesive layer 104 via the second conductive connector 111 and the first conductive connector 107, respectively.

In some embodiments shown in FIG. 3, a case that the first conductive connector 107 is connected to the negative terminal N− and the second conductive connector 111 is connected to the positive terminal N+ is taken as an example for illustration. In other embodiments, the first conductive connector 107 may be connected to the positive terminal N+, and the second conductive connector 111 may be connected to the negative terminal N−.

Since the second conductive connector 111 abuts against at least one of the circuit board 105 or the conductive plate 110, when detaching the display module 103, after the display module 103 is separated from the support frame 100 as the electrically debondable adhesive layer 104 loses adhesion, the circuit board 105 and the conductive plate 110 are non-destructively separated from each other at the abutment position, without destructive detachment of the circuit structure between the circuit board 105 and the conductive plate 110, thereby facilitating non-destructive detachment of the circuit structure connected to the circuit board 105.

In some embodiments, an upper end of the second conductive connector 111 is fixed relative to the conductive plate 110, and a lower end of the second conductive connector 111 abuts against the circuit board 105. In one embodiment, the upper end of the second conductive connector 111 abuts against the conductive plate 110, and the lower end of the second conductive connector 111 abuts against the circuit board 105. In this embodiment, since it is required that the lower end of the second conductive connector 111 aligns with the negative terminal N− or the positive terminal N+ of the circuit board 105 in a point-to-point manner to achieve accurate electrical connection and fixation, high alignment accuracy is required.

In some embodiments, one end of the second conductive connector 111 facing the circuit board 105 is fixed to the circuit board 105, and another end of the second conductive connector 111 facing the conductive plate 110 abuts against the conductive plate 110. As shown in FIG. 3, the lower end of the second conductive connector 111 may be fixed to the circuit board 105 and electrically connected to the negative terminal N− or the positive terminal N+, and the upper end of the second conductive connector 111 abuts against the conductive plate 110. In this way, to implement point-to-point fixed connection between the lower end of the second conductive connector 111 and the circuit board 105, the lower end of the second conductive connector 111 is aligned with the negative terminal N− or the positive terminal N+ of the circuit board 105 in a point-to-point manner in advance to achieve accurate electrical connection and fixation. The upper end of the second conductive connector 111 abuts against the conductive plate 110 in a point-to-surface manner, and the upper end of the second conductive connector 111 may abut against any position on the lower surface of the conductive plate 110 which has a whole surface structure, thereby reducing the requirement for alignment accuracy of the second conductive connector 111 at the abutment position during an assembly process of the display module.

Referring to FIG. 4, FIG. 4 is a schematic structural diagram of a display apparatus provided according to some embodiments of the present disclosure. On the basis of other embodiments, in the display apparatus shown in FIG. 4, a surface of the display module 103 facing away from a display side of the display module 103 is fixed to a conductive plate 110. The conductive plate 110 is fixed to the first surface 101 via the electrically debondable adhesive layer 104 and is electrically connected to the electrically debondable adhesive layer 104. The conductive plate 110 is insulated from the conductive strip 112, for example, a side of the conductive strip 112 facing the conductive plate 110 is provided with an insulating adhesive layer (i.e., the second insulating adhesive layer 113 hereinafter).

In some embodiments shown in FIG. 4, the support frame 100 is a metal frame. The circuit board 105 includes a positive terminal N+ and a negative terminal N− that are connected to a power circuit. One of the positive terminal N+ and the negative terminal N− is electrically connected to the first conductive connector 107, and the other is electrically connected to the metal frame. In FIG. 4, a case where the metal frame is electrically connected to the negative terminal N− and the first conductive connector 107 is electrically connected to the positive terminal N+ is taken as an example for illustration. In other embodiments, the metal frame may be electrically connected to the positive terminal N+, and the first conductive connector 107 is electrically connected to the negative terminal N−.

As shown in FIG. 4, the metal frame is further electrically connected to the conductive plate 110. In this way, one of the positive terminal N+ and the negative terminal N− is electrically connected to one position of the electrically debondable adhesive layer 104 via the metal frame and the conductive plate 110 in sequence, and the other of the positive terminal N+ and the negative terminal N− is electrically connected to another position of the electrically debondable adhesive layer 104 via the first conductive connector 107 and the conductive strip 112 in sequence, and a predetermined voltage is provided for the electrically debondable adhesive layer 104 based on the two different positions. In some embodiments, the metal frame and the conductive plate 110 are electrically connected to each other via a third conductive connector 114.

In some embodiments shown in FIG. 4, the metal frame may be used as a circuit connection structure of one electrode terminal, and the second conductive connector 111 is not needed. The predetermined voltage is provided for the electrically debondable adhesive layer 104 only via the first conductive connector 107.

In some embodiments of the present disclosure, as shown in FIG. 4, the metal frame includes a first region 115 and a second region 116. In the first region 115, the metal frame and the conductive plate 110 are bonded to each other via the electrically debondable adhesive layer 104, and a first insulating adhesive layer 117 is provided between the electrically debondable adhesive layer 104 and the metal frame. In the second region 116, the metal frame and the conductive plate 110 are electrically connected to each other via a third conductive connector 114, and the third conductive connector 114 abuts against at least one of the conductive plate 110 or the first surface 101. In some embodiments, the first insulating adhesive layer 117 may be a pressure-sensitive adhesive (PSA).

When the metal frame is used as the circuit structure connected to the circuit board 105 to supply power to the electrically debondable adhesive layer 104, and the conductive plate 110 and the metal frame are electrically connected to each other via the third conductive connector 114, the third conductive connector 114 is arranged to abut against at least one of the conductive plate 110 or the first surface 101. When detaching the display module 103, after the display module 103 is separated from the metal frame 100, the third conductive connector 114 is synchronously separated at the abutment position, thereby facilitating non-destructive separation of the circuit structure between the conductive plate 110 and the metal frame.

In some embodiments, the third conductive connector 114 abuts against one of the conductive plate 110 and the first surface 101, and is fixedly connected to the other. In this manner, one end of the third conductive connector 114 is fixed, and the other end abuts against the structural element facing the third conductive connector 114. During the installation and detachment process of the display module 103, one end of the third conductive connector 114 may be fixed to avoid the third conductive connector 114 from falling off and being lost, and in addition, facilitate the installation and detachment of the structural elements in the display apparatus.

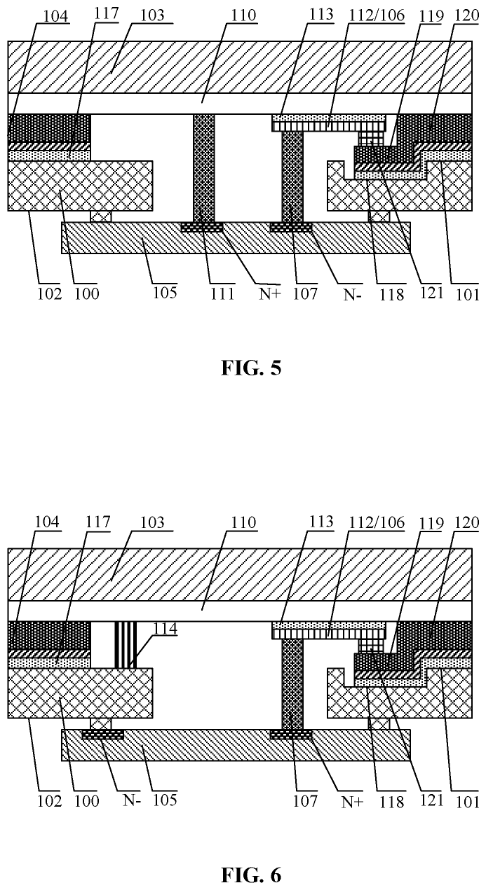

Referring to FIG. 5, FIG. 5 is a schematic structural diagram of a display apparatus provided according to some embodiments of the present disclosure. On the basis of other embodiments, in the display apparatus shown in FIG. 5, the first surface 101 is provided with a groove 118, and the electrically debondable adhesive layer 104 includes: a first portion 119 located in the groove 118 and a second portion 120 located outside the groove. In a direction (the vertical direction in FIG. 5) perpendicular to the first surface, the first portion 119 has an overlapping region with the conductive strip 112, and is electrically connected to the conductive strip 112 in the overlapping region; the second portion 120 has no overlapping region with the conductive strip 112, and is bonded and fixed to the display module 103.

In some embodiments shown in FIG. 5, when the first portion 119 is accommodated in the groove 118, a height difference is formed between the first portion 119 and the second portion 120, with the second portion 120 having a larger height. The height difference allows the first portion 119 to be electrically connected to the conductive strip 112, and the upper surface of the second portion 120 can be fitted and fixed flush with the conductive strip 112 on the same surface. When the back surface of the display module 103 is not provided with a conductive plate 110, the surface on which the upper surface of the second portion 120 is fitted and fixed may be the back surface of the display module 103; and when the back surface of the display module 103 is provided with a conductive plate 110, the surface may be the back surface of the conductive plate 110. In this way, by bending the electrically debondable adhesive layer 104 with a uniform thickness into a Z-shaped structure as shown in FIG. 5, it can adapt to the pattern structure of the groove 118, and the display module 103 is bonded to the first surface 101, without the need for an electrically debondable adhesive layer 104 with non-uniform thickness as shown in FIG. 4, nor the need to bend the electrically debondable adhesive layer 104 to the second surface 102 as shown in FIG. 2, thereby reducing the assembly process difficulty of the display apparatus.

When the groove 118 is provided on the first surface 101, the circuit connection shown in FIG. 5 may be implemented based on the display apparatus shown in FIG. 3, and the circuit board 105 is connected to different positions of the electrically debondable adhesive layer 104 via the first conductive connector 107 and the second conductive connector 111, respectively.

Referring to FIG. 6, FIG. 6 is a schematic structural diagram of a display apparatus provided according to some embodiments of the present disclosure. On the basis of other embodiments, in the display apparatus shown in FIG. 6, when the groove 118 is provided on the first surface 101, the circuit connection shown in FIG. 6 may be implemented based on the display apparatus shown in FIG. 4, and the circuit board 105 is connected to different positions of the electrically debondable adhesive layer 104 via the first conductive connector 107 and the metal frame, respectively.

In some embodiments of the present disclosure, as shown in FIG. 5 or FIG. 6, a surface of the display module 103 facing away from a display side of the display module 103 is fixed to a conductive plate 110, and the conductive plate 110 is fixed to the first surface 101 via the electrically debondable adhesive layer 104; the conductive plate 110 is electrically connected to the electrically debondable adhesive layer 104 and insulated from the conductive strip 112; the first portion 119 is electrically connected to the conductive strip 112, and the second portion 120 is electrically connected to the conductive plate 110. In this manner, the conductive plate 110 and the conductive strip 112 are electrically connected to different positions of the electrically debondable adhesive layer 104, and the circuit board 105 applies a predetermined voltage to different positions of the electrically debondable adhesive layer 104 via the conductive plate 110 and the conductive strip 112, respectively.

In some embodiments, as shown in any implementation of FIG. 5 or FIG. 6, the first portion 119 and the conductive strip 112 are electrically connected to each other via a fourth conductive connector 121, and the fourth conductive connector 121 abuts against at least one of the first portion 119 or the conductive strip 112. In this embodiment, a gap is formed between the first portion 119 and the conductive strip 112 based on the groove 118, and the fourth conductive connector 121 is arranged in the gap to electrically connect the first portion 119 and the conductive strip 112, thereby facilitating the circuit connection between the first portion 119 and the conductive strip 112. In addition, since the fourth conductive connector 121 abuts against at least one of the first portion 119 or the conductive strip 112, and the conductive strip 112 is fixed to the display module 103, when detaching the display module 103, the fourth conductive connector 121 is synchronously and non-destructively separated at the abutment position, thereby realizing non-destructive separation of the circuit connection structure between the first portion 119 and the conductive strip 112.

In some embodiments, as shown in any implementation of FIG. 5 or FIG. 6, one end of the fourth conductive connector 121 facing the first portion 119 is bonded and fixed to the first portion 119, and one end of the fourth conductive connector 121 facing the conductive strip 112 abuts against the conductive strip 112. In this manner, the lower surface of the fourth conductive connector 121 is directly bonded and fixed to the first portion 119 based on the electrically debondable adhesive layer 104, without an additional adhesive layer for bonding and fixing the fourth conductive connector 121. The upper surface of the fourth conductive connector 121 abuts against the conductive strip 112 due to the pressing force from installation of the display module 103, thereby facilitating the installation and detachment of the structural elements in the display apparatus.

In some embodiments, as shown in any implementation of any of FIG. 3 to FIG. 6, a surface of the display module 103 facing away from a display side is fixed to a conductive plate 110, and the conductive plate 110 is bonded and fixed to the first surface 101 via the electrically debondable adhesive layer 104; the conductive plate 110 is electrically connected to the electrically debondable adhesive layer 104; the conductive strip 112 is fixed to a surface of the conductive plate 110 via a second insulating adhesive layer 113, and the conductive strip 112 is insulated from the conductive plate 110. In some embodiments, the second insulating adhesive layer 113 may be an insulating double-sided adhesive.

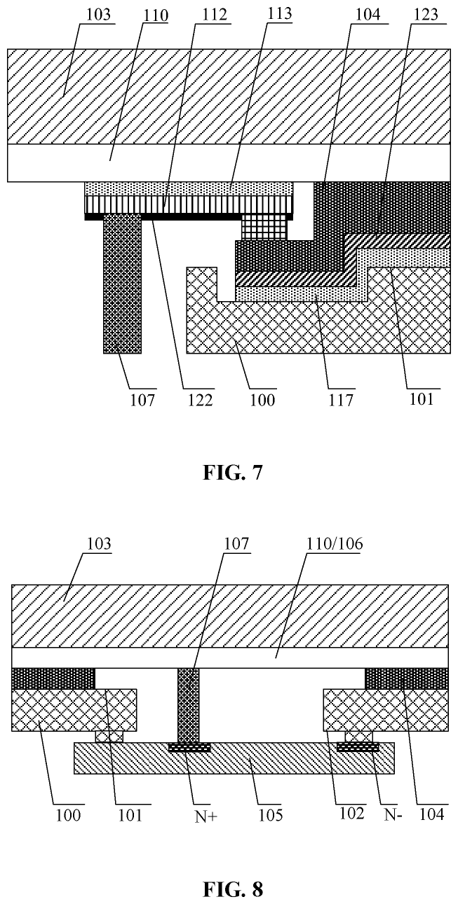

Referring to FIG. 7, FIG. 7 is a partial enlarged view of a display apparatus in a conductive strip region provided according to some embodiments of the present disclosure. On the basis of other embodiments, in the display apparatus shown in FIG. 7, a surface of the conductive strip 112 facing the support frame 100 is covered with an insulating layer 122, and the insulating layer 122 exposes a region of the conductive strip 112 connecting the first conductive connector 107 and a region of the conductive strip 112 connecting the electrically debondable adhesive layer 104. As shown in FIG. 7, the insulating layer 122 is provided with an exposed region corresponding to the upper end of the first conductive connector 107 and an exposed region corresponding to the upper end of the fourth conductive connector 121, and the conductive strip 112 is electrically connected to the upper end of the first conductive connector 107 and the upper end of the fourth conductive connector 121 at the corresponding exposed regions, respectively.

In some embodiments, the conductive strip 112 may be any one of: a metal layer, a conductive oxide (such as ITO) layer, a graphene layer, a graphite layer, and a carbon nanotube layer. These materials exhibit high electrical conductivity, which can not only effectively reduce circuit resistance, but also facilitate the formation of a thin film structure, thereby reducing the resistance while reducing the influence on the product thickness.

As shown in FIG. 7, if the display module 103 is fixed to the conductive plate 110, the conductive strip 112 is fixed to the surface of the conductive plate 110 via the second insulating adhesive layer 113. If the conductive plate 110 is not provided, the conductive strip 112 is fixed to the back surface of the display module 103 via the second insulating adhesive layer 113.

In some embodiments shown in FIG. 7, in a case that the support frame 100 is a metal frame, by covering the surface of the conductive strip 112 facing the support frame 100 with the insulating layer 122, the requirement for the spacing between the conductive strip 112 and the metal frame below is reduced, thereby reducing the thickness of the display apparatus while preventing the short circuit problem between the conductive strip 112 and the metal frame. In some embodiments based on other embodiments, as shown in FIG. 7, the support frame 100 is a metal frame. The electrically debondable adhesive layer 104 is bonded and fixed to the first surface 101 via a first insulating adhesive layer 117, and a conductive layer 123 is further provided between the first insulating adhesive layer 117 and the electrically debondable adhesive layer 104. Based on the conductive layer 123, the circuit resistance is reduced, to reduce the predetermined voltage for controlling the electrically debondable adhesive layer 104 to lose adhesion, thereby reducing energy consumption.

In other solutions, if there is a relatively large distance between the metal frame and the conductive strip 112, the risk of short circuit between them is relatively low. In this case, the insulating layer 122 may not be provided, and the conductive strip 112 is directly exposed.

In some embodiments, the conductive layer 123 may be any one of: a metal layer, a composite conductive layer, a graphene layer, a graphite layer, and a carbon nanotube layer. These materials exhibit high electrical conductivity, which can not only effectively reduce circuit resistance, but also facilitate the formation of a thin film structure, thereby reducing the resistance while reducing the influence on the product thickness.

Referring to FIG. 8, FIG. 8 is a schematic structural diagram of a display apparatus provided according to some embodiments of the present disclosure. On the basis of other embodiments, in the display apparatus shown in FIG. 8, a surface of the display module 103 facing away from a display side of the display module 103 is fixed to a conductive plate 110, and the conductive plate 110 is fixed to the first surface 101 via the electrically debondable adhesive layer 104. The support frame 100 is a metal frame, and the electrically debondable adhesive layer 104 is electrically connected to the conductive plate 110 and the metal frame, respectively. The conductive element 106 includes the conductive plate 110. The circuit board 105 includes a positive terminal N+ and a negative terminal N− of a power circuit. One of the positive terminal N+ and the negative terminal N− is connected to the first conductive connector 107, and the other is electrically connected to the metal frame. The first conductive connector 107 abuts against at least one of the conductive plate 110 or the circuit board 105.

In some embodiments shown in FIG. 8, the metal frame is additionally used as an electrode structure of the circuit board 105, and the circuit board 105 applies a predetermined voltage to two opposite surfaces of the electrically debondable adhesive layer 104 via the metal frame and the first conductive connector 107, respectively, to control the electrically debondable adhesive layer 104 to lose adhesion when detaching the display module 103. In this embodiment, no additional adhesive layer (such as the PSA mentioned above) is required to be provided between the electrically debondable adhesive layer 104 and the metal frame. This arrangement not only employs the metal frame as an electrode structure, but also eliminates one insulating adhesive layer, thus reducing product thickness.

In some embodiments, the electrically debondable adhesive layer 104 is in direct contact with the conductive plate 110 and the metal frame, to implement the electrical connection between the electrically debondable adhesive layer 104 and the conductive plate 110, and the electrical connection between the electrically debondable adhesive layer 104 and the metal frame.

In a case that the metal frame is electrically connected to the circuit board 105, in some embodiments, as shown in FIG. 8, the metal frame and the circuit board 105 are in electrical contact. For example, the circuit board 105 may be directly fixed to the metal frame via a screw or a snap-fit device to implement electrical contact, which not only enables the electrical connection between the metal frame and the circuit board 105, but also facilitates the installation and detachment of the circuit board 105 on the metal frame.

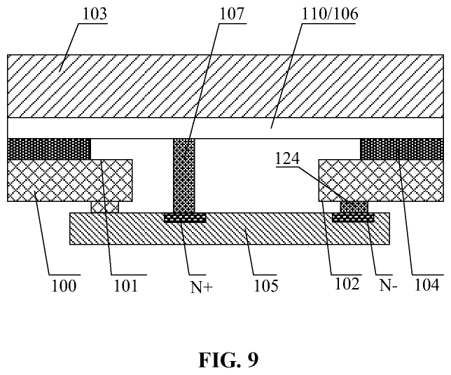

Referring to FIG. 9, FIG. 9 is a schematic structural diagram of a display apparatus provided according to some embodiments of the present disclosure. On the basis of other embodiments, in the display apparatus shown in FIG. 9, the metal frame and the circuit board 105 are electrically connected to each other via a fifth conductive connector 124, and the fifth conductive connector 124 abuts against at least one of the metal frame or the circuit board 105. In this embodiment, when detaching the circuit board 105 from the metal frame, after the circuit board 105 is separated from the metal frame, the fifth conductive connector 124 is non-destructively separated at the abutment position, thereby facilitating non-destructive detachment of the circuit structure connected to the circuit board 105.

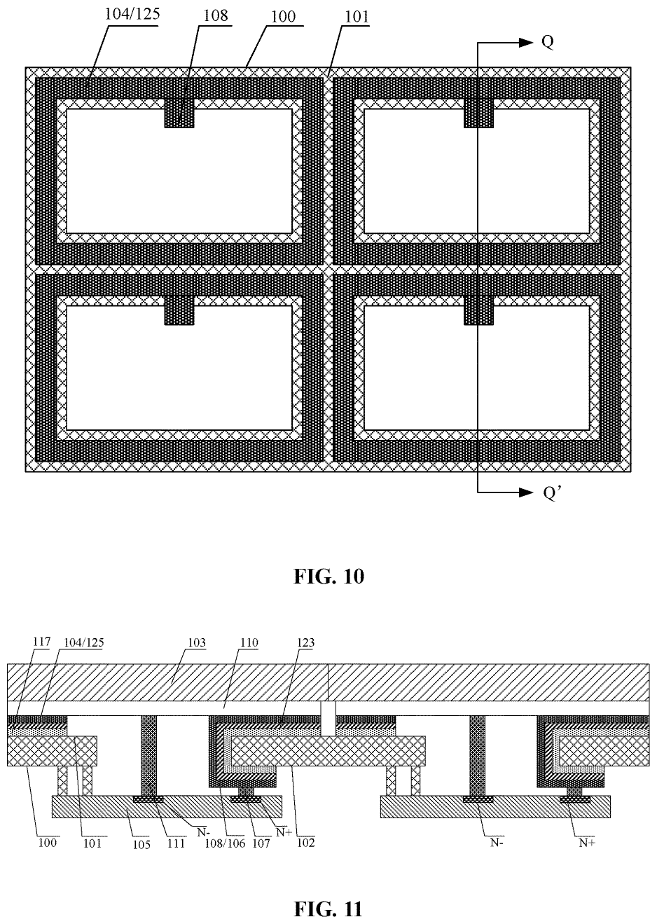

Referring to FIG. 10 and FIG. 11, FIG. 10 is a top view of a display apparatus provided according to some embodiments of the present disclosure, and FIG. 11 is a cross-sectional view of the display apparatus shown in FIG. 10 along a Q-Q′ direction. To facilitate illustrating the relative positions of the support frame 100 and the electrically debondable adhesive layer 104, only the support frame 100 and the electrically debondable adhesive layer 104 are shown in the top view of the display apparatus in FIG. 10, and other related structures may refer to the description of other embodiments of the present disclosure.

On the basis of other embodiments, in the display apparatus shown in FIG. 10 and FIG. 11, the display apparatus includes multiple display modules 103. For each display module 103 of the multiple display modules 103, a side of the display module 103 facing away from a display side of the display module 103 is fixed to a surface of a respective independent conductive plate 110. All the conductive plates 110 are fixed to the first surface 101 via the electrically debondable adhesive layer 104. According to this embodiment, in the display apparatus, multiple display modules 103 are fixed on the same side of the support frame 100 seamlessly and coplanarly via the electrically debondable adhesive layer 104, and a large-area spliced display apparatus is constructed.

In the embodiments shown in FIG. 10 and FIG. 11, the circuit board 105 is configured to provide the predetermined voltage for the electrically debondable adhesive layer 104 via the first conductive connector 107 and the second conductive connector 111. The electrically debondable adhesive layer 104 includes a bent portion 108 extending to the second surface 102, and the first conductive connector 107 is connected between the bent portion 108 and the circuit board 105. The second conductive connector 111 is connected between the conductive plate 110 and the circuit board 105.

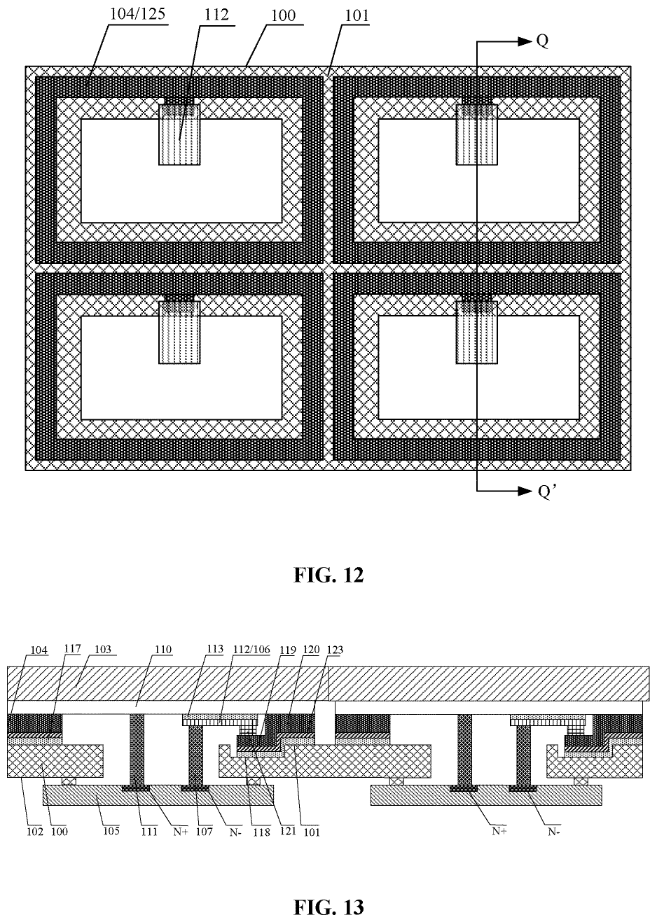

Referring to FIG. 12 and FIG. 13, FIG. 12 is a top view of a display apparatus provided according to some embodiments of the present disclosure, and FIG. 13 is a cross-sectional view of the display apparatus shown in FIG. 12 along the Q-Q′ direction. To facilitate illustrating the relative positions of the support frame 100 and the electrically debondable adhesive layer 104, only the support frame 100, the electrically debondable adhesive layer 104, and the conductive strip 112 are shown in the top view of the display apparatus in FIG. 12, and other related structures may refer to the description of other embodiments of the present disclosure.

On the basis of other embodiments, in the display apparatus shown in FIG. 12 and FIG. 13, the display apparatus includes multiple display modules 103. For each display module 103 of the multiple display modules 103, a side of the display module 103 facing away from a display side of the display module 103 is fixed to a surface of a respective independent conductive plate 110. All the conductive plates 110 are fixed to the first surface 101 via the electrically debondable adhesive layer 104. Similar to the embodiments shown in FIG. 10 and FIG. 11, according to some embodiments shown in FIG. 12 and FIG. 13, in the display apparatus, multiple display modules 103 are fixed on the same side of the support frame 100 seamlessly and coplanarly via the electrically debondable adhesive layer 104, and a large-area spliced display apparatus is constructed.

In some embodiments shown in FIG. 12 and FIG. 13, a groove 118 is provided on the first surface 101. The electrically debondable adhesive layer 104 includes: a first portion 119 located in the groove 118 and a second portion 120 located outside the groove. The first portion 119 is connected to the conductive strip 112 on the back surface of the conductive plate 110. The circuit board 105 is configured to provide the predetermined voltage for the electrically debondable adhesive layer 104 via the first conductive connector 107 and the second conductive connector 111. The first conductive connector 107 is connected between the conductive strip 112 and the circuit board 105. The second conductive connector 111 is connected between the conductive plate 110 and the circuit board 105.

As shown in FIG. 10 to FIG. 13, when multiple display modules 103 are provided, and each display module 103 is fixed to a respective conductive plate 110, in some embodiments, the electrically debondable adhesive layer 104 includes multiple adhesive frames 125 isolated from each other. The adhesive frames 125 are in one-to-one correspondence with the conductive plates 110, and each adhesive frame 125 is bonded and fixed to a peripheral edge of the corresponding conductive plate 110 and is in electrical contact with the corresponding conductive plate 110. The circuit board 105 includes a positive terminal N+ and a negative terminal N− that are connected to a power circuit. Each adhesive frame 125 is electrically connected to a respective independent conductive element 106. For each display module 103, the adhesive frame 125 corresponding to the display module 103 is connected to a first conductive connector 107 and a second conductive connector 111. For the first conductive connector 107 and the second conductive connector 111 corresponding to the same display module 103, one of the first conductive connector 107 and the second conductive connector 111 is electrically connected to the positive terminal N+, and the other is electrically connected to the negative terminal N−.

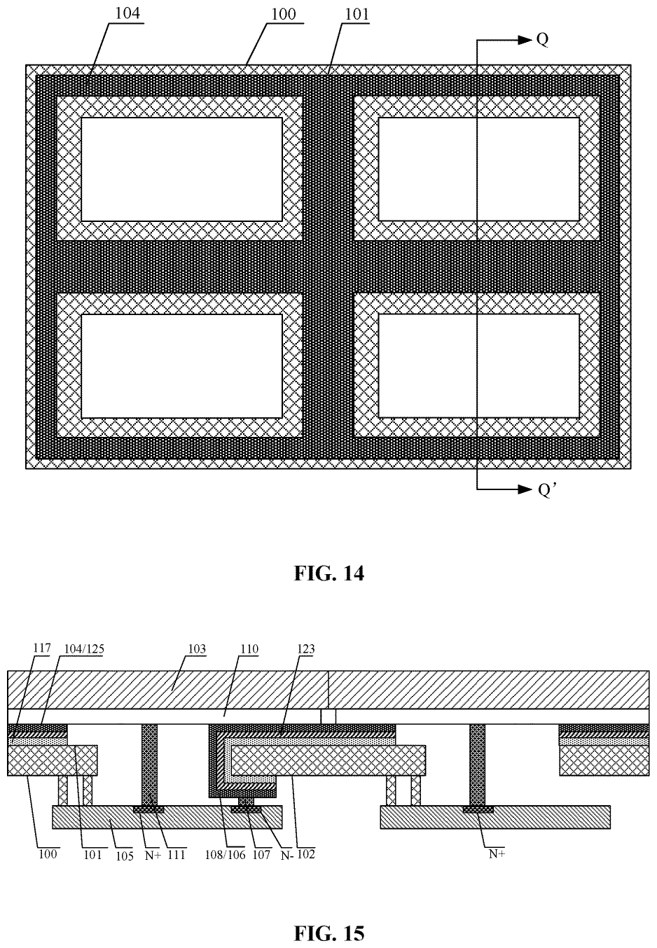

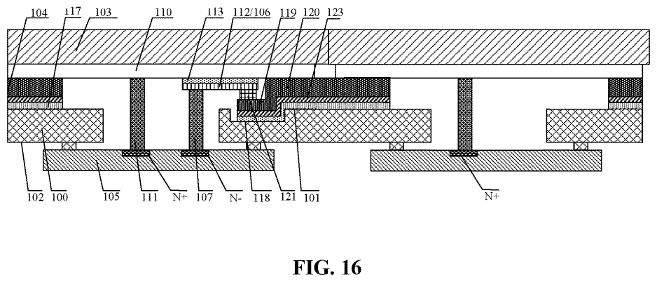

Referring to FIG. 14 to FIG. 16, FIG. 14 is a top view of a display apparatus provided according to some embodiments of the present disclosure, FIG. 15 is a cross-sectional view of the display apparatus shown in FIG. 14 along the Q-Q′ direction, and FIG. 16 is another cross-sectional view of the display apparatus shown in FIG. 14 along the Q-Q′ direction. FIG. 15 shows a manner in which the electrically debondable adhesive layer 104 is connected to the first conductive connector 107 via the bent portion 108, and FIG. 16 shows a manner in which the electrically debondable adhesive layer 104 is connected to the first conductive connector 107 via the conductive strip 112.

On the basis of other embodiments, in the display apparatus shown in FIG. 14 to FIG. 16, when multiple display modules 103 are provided and each display module 103 is fixed to a respective conductive plate 110, the respective conductive plates 110 are bonded and fixed to the support frame 100 via the same layer of the electrically debondable adhesive layer 104. The electrically debondable adhesive layer 104 includes multiple adhesive frames 125 in one-to-one correspondence with the conductive plates 110, and each adhesive frame 125 is bonded and fixed to a peripheral edge of the corresponding conductive plate 110. All the adhesive frames 125 form an integrally electrically connected structure, and each adhesive frame is in electrical contact with the corresponding conductive plate 110. The circuit board 105 includes multiple positive terminals N+ and a negative terminal N− that are connected to a power circuit, and the first conductive connector 107 is electrically connected to the negative terminal N−. The multiple positive terminals N+ are in one-to-one correspondence with the conductive plates 110, and each positive terminal is electrically connected to the corresponding conductive plate 110 via a respective second conductive connector 111. The second conductive connector 111 abuts against at least one of the circuit board 105 or the conductive plate 110.

When adhesive frames 125 that are integrally and electrically connected are used for the display modules 103, all the display modules 103 are bonded and fixed to the support frame 100 using a whole layer of the electrically debondable adhesive layer 104, and each display module 103 is provided with a respective independent conductive plate 110. The first conductive connector 107 is electrically connected to the negative terminal N−. Each positive terminal is electrically connected to the corresponding conductive plate 110 via a respective second conductive connector 111. In this way, each display module 103 is connected to a high level via a respective independent positive terminal N+, and all the display modules 103 are connected to a low level via the same negative terminal N−. All the display modules 103 share the same first conductive connector 107 and the negative terminal N−, and it is only required that one display module 103 is provided with one first conductive connector 107 and one negative terminal N−. Therefore, independent control of losing adhesion of the electrically debondable adhesive layer 104 for each display module 103 is realized, and the number of the first conductive connectors 107 and the negative terminals N− is reduced.

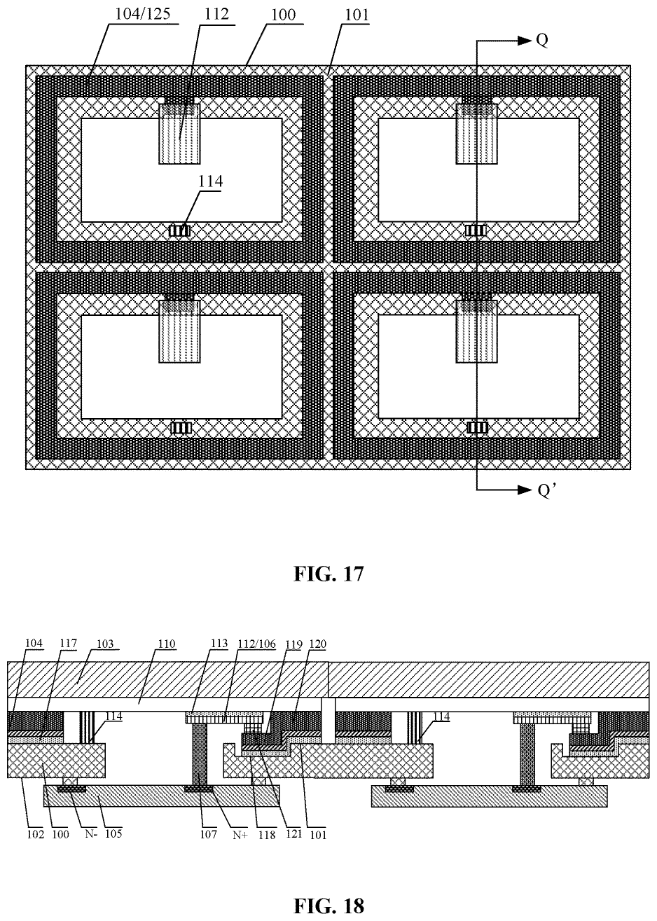

Referring to FIG. 17 and FIG. 18, FIG. 17 is a top view of a display apparatus provided according to some embodiments of the present disclosure, and FIG. 18 is a cross-sectional view of the display apparatus shown in FIG. 17 along the Q-Q′ direction. To facilitate illustrating the relative positions of the support frame 100 and the electrically debondable adhesive layer 104, only the support frame 100, the conductive strip 112, the third conductive connector 114, and the electrically debondable adhesive layer 104 are shown in the top view of the display apparatus in FIG. 17, and other related structures may refer to the description of other embodiments of the present disclosure.

On the basis of other embodiments, in the display apparatus shown in FIG. 17 and FIG. 18, when multiple display modules 103 are provided, and each display module 103 is fixed to the corresponding conductive plate 110, the electrically debondable adhesive layer 104 includes multiple adhesive frames 125 isolated from each other. The adhesive frames 125 are in one-to-one correspondence with the conductive plates 110, and each adhesive frame 125 is bonded and fixed to a peripheral edge of the corresponding conductive plate 110 and is in electrical contact with the corresponding conductive plate 110. The circuit board 105 includes a positive terminal N+ and a negative terminal N− that are connected to a power circuit. Each adhesive frame 125 is electrically connected to a respective independent conductive element 106, and each first conductive connector 107 is electrically connected to a respective positive terminal N+. The support frame 100 is a metal frame, and the metal frame is electrically connected to the negative terminal N−. This embodiment is illustrated by taking the conductive element 106 being the conductive strip 112 as an example.

In the display apparatus shown in FIG. 17 and FIG. 18, the metal frame is additionally used as an electrode structure and is connected to the negative terminal N−, thereby being connected to the same low level. For each display module 103, a respective high level is applied to the adhesive frame 125 corresponding to the display module 103 via an individual first conductive connector 107. In this way, a predetermined voltage is inputted to a respective adhesive frame 125 corresponding to each display module 103 individually, and the adhesive frames 125 corresponding to the display modules 103 can be individually controlled to lose adhesion, and the display modules 103 can be independently detached.

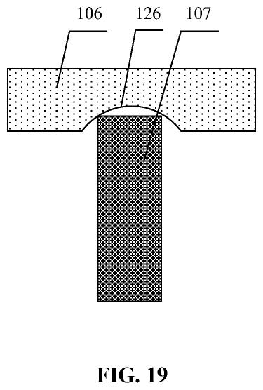

Referring to FIG. 19, FIG. 19 is a partial enlarged schematic diagram of a first conductive connector and a conductive element at an abutment position in a display apparatus provided according to some embodiments of the present disclosure. On the basis of other embodiments, in the display apparatus shown in FIG. 19, a surface of the conductive element 106 facing the circuit board 105 is provided with a position-limiting groove 126, and the position-limiting groove 126 is configured to accommodate an end portion of the first conductive connector 107 facing away from the circuit board 105. In this manner, by using the position-limiting groove 126, the position of the end portion of the first conductive connector 107 that abuts against the conductive element 106 can be limited, to avoid the end portion from shifting and improve stability.

In some embodiments, in order to improve the adaptability between the first conductive connector 107 and the conductive element 106, the end portion of the first conductive connector 107 abutting against the conductive element 106 may be shaped to match the position-limiting groove 126. If the position-limiting groove 126 is an arcuate groove, the end portion may be an arcuate protrusion that seamlessly contacts the arcuate groove; and if the position-limiting groove 126 is a rectangular groove, the end portion may be a rectangular end portion that seamlessly contacts the rectangular groove.

In some embodiments of the present disclosure, one end of the first conductive connector 107 facing the circuit board 105 is fixed to the circuit board 105, and one end of the first conductive connector 107 facing the conductive element 106 abuts against the conductive element 106. In this way, the upper end of the first conductive connector 107 abuts against the conductive element 106 in a point-to-surface manner, and the upper end of the first conductive connector 107 may abut against any position on the lower surface of the conductive element 106 which has a whole surface structure, thereby reducing the requirement for alignment accuracy of the first conductive connector 107 at the abutment position during an assembly process of the display module. To implement point-to-point fixed connection between the lower end of the first conductive connector 107 and the circuit board 105, the lower end of the first conductive connector 107 is aligned with the negative terminal N− or the positive terminal N+ of the circuit board 105 in a point-to-point manner in advance to achieve accurate electrical connection and fixation.

During detaching the display module, it is necessary to clamp the related welded electrode structure, which results in low efficiency and poor safety. If a plug-in design is adopted to expose the related electrode structure, a special design is required, and the electrode structure needs to be plugged into/welded with the circuit board, which will affect subsequent disassembly and replacement. In the embodiments of the present disclosure, by providing the electrical connection manner in which at least one end of the conductive connector in the display apparatus abuts against the structural element facing the conductive connector, based on the pressing force after the display module 103 is installed, a safe and reliable electrical connection at the abutment position is achieved. Moreover, when the display module 103 is detached, as the display module 103 is separated from the support frame 100, the pressing force at the abutment position is automatically released, and the conductive connector is automatically and non-destructively separated at the abutment position.

In some embodiments of the present disclosure, at least one of conductive connectors including the first conductive connector 107 to the fifth conductive connector 124 includes a compressible portion. For a conductive connector having a compressible portion, after the display module 103 is bonded and fixed to the support frame 100 via the electrically debondable adhesive layer 104, the compressible portion may be compressed based on the pressing force after the display module 103 is bonded and fixed, and safe and reliable electrical connection of the conductive connector is implemented at the abutment position. When the display module 103 is detached, as the display module 103 is separated, the compressed compressible portion is released, thereby achieving non-destructive separation at the abutment position.

In some embodiments, at least one of conductive connectors including the first conductive connector 107 to the fifth conductive connector 124 may be any one of: a retractable probe, conductive foam, conductive cloth, conductive elastic piece, and conductive spring, and the conductive connector has a compressible portion. A conductive connector having a compressible portion can be configured to abut against the facing structural element to achieve non-welded flexible connection. Compared with a welded fixed solution, after the display module 103 is detached, non-destructive automatic separation can be achieved at the abutment position. Cooperating with related circuit path design, the function of rapid disassembly of structural elements in the display apparatus can be realized, without the need for additional clamping/plugging actions, nor the need for disassembling the circuit board and other actions, thereby achieving rapid non-destructive disassembly of related circuit connection structures.

In some embodiments, if at least one of the first conductive connector 107 to the fifth conductive connector 124 has a compressible portion, a height compression range of the compressible portion of the compressible conductive connector is 0.5 mm to 1 mm. This height compression range is moderately valued. On the one hand, it can avoid the problem of poor electrical contact at the abutment position caused by insufficient compression height resulting in weak force at the abutment position. On the other hand, it can avoid the problems of inconvenient installation due to excessively large force at the abutment position caused by excessively large compression height, as well as the adverse effect on the stability between structural elements.

In the embodiments of the present disclosure, based on the abutment electrical connection design between the conductive connector and the facing structural element, flexible connection at the abutment position is achieved, and non-destructive separation at the abutment position can be realized, thereby facilitating detachment of the structural elements.

In a conventional solution of implementing detachability of the display module using an electrically debondable adhesive layer, it is generally necessary to expose an electrode structure for connection to a power supply. In one embodiment of the present disclosure, it is not required to expose the electrode. The circuit board is connected to the power supply based on the power supply structure of the display apparatus, the predetermined voltage is provided for the electrically debondable adhesive layer 104 by using the positive terminal N+ and the negative terminal N−.

In some embodiments, the display apparatus may display virtual touch keys to trigger a detachment instruction. The circuit board 105 may provide the predetermined voltage for the electrically debondable adhesive layer 104 corresponding to a display module 103 according to the detachment instruction, to detach the display module 103. In one embodiment, a mechanical key is provided on the display apparatus to trigger the detachment instruction. When multiple display modules 103 are provided, the predetermined voltage is independently provided for the adhesive frame or conductive plate 110 corresponding to the display module 103 to be detached, and independent detachment control of each display module 103 can be realized.

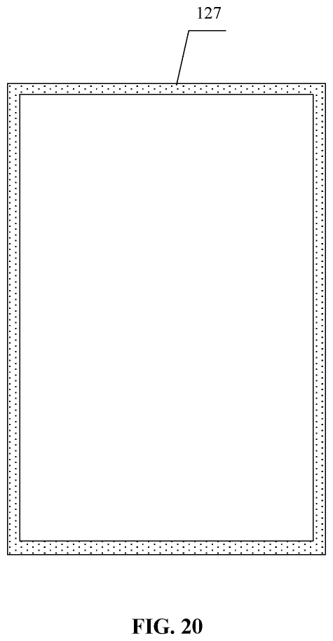

Based on the display apparatus provided by the above embodiments, in some embodiments of the present disclosure, an electronic device is further provided, as shown in FIG. 20.

Referring to FIG. 20, FIG. 20 is a schematic structural diagram of an electronic device provided according to some embodiments of the present disclosure, and the electronic device includes the display apparatus 127 provided by the above embodiments.

The electronic device embodiment disclosed in the above embodiment has the same or corresponding beneficial effects as the display apparatus embodiment. To avoid repetition, it will not be repeated here.

The embodiments in the specification of the present disclosure are described in a progressive, or parallel, or a combination of progressive and parallel manner. Each embodiment focuses on differences from other embodiments, and the same and similar parts between the embodiments may refer to each other. The embodiments provided in the embodiments of the present disclosure may be combined with each other if they are not contradictory.

In the description of the present disclosure, the description of the accompanying drawings and the embodiments is illustrative rather than restrictive. The same reference numerals throughout the specification and the embodiments identify the same structures. In addition, for ease of understanding and description, the drawings may exaggerate the thicknesses of some layers, films, panels, regions, etc. It can also be understood that when an element such as a layer, film, region, or substrate is referred to as being “on” another element, the element can be directly on the other element or there may be an intermediate element. In addition, “on . . . ” means positioning an element on or below another element, but essentially does not mean positioning on the upper side of another element according to the direction of gravity.

The orientation or position relationships indicated by the terms “upper”, “lower”, “top”, “bottom”, “inner”, “outer”, etc. are based on the orientation or position relationships shown in the accompanying drawings, and are only for the convenience of describing the present disclosure and simplifying the description, rather than indicating or implying that the referred device or element must have a specific orientation, be constructed and operated in a specific orientation, and therefore cannot be understood as a limitation to the present disclosure. When a component is considered to be “connected” to another component, it may be directly connected to the other component or there may be a centrally arranged component at the same time.

It should further be noted that in the present disclosure, relational terms such as first and second, etc., are only used to distinguish one entity or operation from another entity or operation, and do not necessarily require or imply any actual relationship or order between these entities or operations. Moreover, the terms “including”, “comprising”, or any other variant thereof are intended to cover non-exclusive inclusion, and an article or device including a series of elements includes not only those elements, but also other elements not explicitly listed, or also includes elements inherent to such article or device. Without more limitations, an element defined by the statement “including a . . . ” does not exclude the existence of other identical elements in the article or device including the above element.

The above description of the disclosed embodiments enables one to implement or use the present disclosure. Various modifications to these embodiments will be apparent, and the general principles defined herein may be implemented in other embodiments without departing from the spirit or scope of the present disclosure. Therefore, the present disclosure will not be limited to these embodiments shown herein, but is to conform to the widest scope consistent with the principles and novel features disclosed herein.

1. A display apparatus, comprising:
a support frame, wherein the support frame comprises a first surface and a second surface opposite to each other;
a display module, wherein the display module is fixed to the first surface via an electrically debondable adhesive layer;
a circuit board, wherein the circuit board positioned on a side of the support frame facing away from the display module;
a conductive element, wherein the conductive element is positioned between the display module and the circuit board, and the conductive element is electrically connected to the electrically debondable adhesive layer; and
a first conductive connector, wherein the circuit board and the conductive element are electrically connected to each other via the first conductive connector, the first conductive connector abuts against at least one of the circuit board or the conductive element, and the circuit board is configured to provide a predetermined voltage for the electrically debondable adhesive layer via the first conductive connector.

2. The display apparatus according to claim 1, wherein the support frame comprises a side surface connecting the first surface and the second surface; the electrically debondable adhesive layer comprises a bent portion, the bent portion extends to the second surface along the side surface, and the bent portion partially overlaps the second surface; a first preset spacing is provided between a part of the bent portion that overlaps the second surface and the circuit board; and the first conductive connector is positioned between the bent portion and the circuit board.

3. The display apparatus according to claim 1, further comprising:
a conductive strip, wherein the conductive strip is positioned on a side of the display module facing the support frame, and the conductive strip is electrically connected to the electrically debondable adhesive layer, and wherein
the conductive element comprises the conductive strip, a second preset spacing is provided between the conductive strip and the circuit board, and the first conductive connector is positioned between the conductive strip and the circuit board.

4. The display apparatus according to claim 3, wherein a surface of the display module facing away from a display side of the display module is fixed to a conductive plate, the conductive plate is fixed to the first surface via the electrically debondable adhesive layer and is electrically connected to the electrically debondable adhesive layer, and the conductive plate is insulated from the conductive strip;
the circuit board comprises a positive terminal and a negative terminal that are connected to a power circuit, one of the positive terminal and the negative terminal is electrically connected to the first conductive connector, and the other of the positive terminal and the negative terminal is electrically connected to one end of a second conductive connector; another end of the second conductive connector is electrically connected to the conductive plate, and wherein
the second conductive connector abuts against at least one of the circuit board or the conductive plate.

5. The display apparatus according to claim 3, wherein a surface of the display module facing away from a display side of the display module is fixed to a conductive plate, the conductive plate is fixed to the first surface via the electrically debondable adhesive layer and is electrically connected to the electrically debondable adhesive layer, and the conductive plate is insulated from the conductive strip;
the support frame is a metal frame;
the circuit board comprises a positive terminal and a negative terminal that are connected to a power circuit, one of the positive terminal and the negative terminal is electrically connected to the first conductive connector, the other of the positive terminal and the negative terminal is electrically connected to the metal frame, and the metal frame is further electrically connected to the conductive plate.

6. The display apparatus according to claim 5, wherein the metal frame comprises a first region and a second region, and wherein
in the first region, the metal frame and the conductive plate are bonded to each other via the electrically debondable adhesive layer, and a first insulating adhesive layer is provided between the electrically debondable adhesive layer and the metal frame;
in the second region, the metal frame and the conductive plate are electrically connected to each other via a third conductive connector, and the third conductive connector abuts against at least one of the conductive plate or the first surface.

7. The display apparatus according to claim 3, wherein the first surface is provided with a groove;
the electrically debondable adhesive layer comprises: a first portion located in the groove and a second portion located outside the groove;
in a direction perpendicular to the first surface, the first portion has an overlapping region with the conductive strip and is electrically connected to the conductive strip in the overlapping region, and the second portion has no overlapping region with the conductive strip and is bonded and fixed to the display module.

8. The display apparatus according to claim 7, wherein a surface of the display module facing away from a display side of the display module is fixed to a conductive plate, and the conductive plate is fixed to the first surface via the electrically debondable adhesive layer, and the conductive plate is electrically connected to the electrically debondable adhesive layer and insulated from the conductive strip;
the first portion is electrically connected to the conductive strip, and the second portion is electrically connected to the conductive plate.

9. The display apparatus according to claim 8, wherein the first portion and the conductive strip are electrically connected to each other via a fourth conductive connector, and the fourth conductive connector abuts against at least one of the first portion or the conductive strip.

10. The display apparatus according to claim 3, wherein a surface of the display module facing away from a display side of the display module is fixed to a conductive plate, the conductive plate is bonded and fixed to the first surface via the electrically debondable adhesive layer, and the conductive plate is electrically connected to the electrically debondable adhesive layer;
the conductive strip is fixed to a surface of the conductive plate via a second insulating adhesive layer;
a surface of the conductive strip facing the support frame is covered with an insulating layer, and the insulating layer exposes a region of the conductive strip connecting the first conductive connector and a region of the conductive strip connecting the electrically debondable adhesive layer.

11. The display apparatus according to claim 1, wherein the support frame is a metal frame;
the electrically debondable adhesive layer is bonded and fixed to the first surface via a first insulating adhesive layer, and a conductive layer is further provided between the first insulating adhesive layer and the electrically debondable adhesive layer.

12. The display apparatus according to claim 1, wherein a surface of the display module facing away from a display side of the display module is fixed to a conductive plate, and the conductive plate is fixed to the first surface via the electrically debondable adhesive layer;
the support frame is a metal frame, and the electrically debondable adhesive layer is electrically connected to the conductive plate and the metal frame;
the conductive element comprises the conductive plate;
the circuit board comprises a positive terminal and a negative terminal of a power circuit, one of the positive terminal and the negative terminal is connected to the first conductive connector, and the other of the positive terminal and the negative terminal is electrically connected to the metal frame.

13. The display apparatus according to claim 12, wherein
the metal frame is in electrical contact with the circuit board; or
the metal frame and the circuit board are electrically connected to each other via a fifth conductive connector, and the fifth conductive connector abuts against at least one of the metal frame or the circuit board.

14. The display apparatus according to claim 1, wherein the display apparatus comprises a plurality of the display modules, and for each display module of the plurality of the display modules, a surface of the display module facing away from a display side of the display module is fixed to a surface of a respective independent conductive plate; and
all the conductive plates are fixed to the first surface via the electrically debondable adhesive layer.

15. The display apparatus according to claim 14, wherein the conductive plates is bonded and fixed to the support frame via a same layer of the electrically debondable adhesive layer, the electrically debondable adhesive layer comprises a plurality of adhesive frames in one-to-one correspondence with the conductive plates, and each adhesive frame of the plurality of adhesive frames is bonded and fixed to a peripheral edge of the corresponding conductive plate, the plurality of adhesive frames form an integrally electrically connected structure, and each adhesive frame of the plurality of adhesive frames is in electrical contact with the corresponding conductive plate;
the circuit board comprises plurality of positive terminals and a negative terminal that are connected to a power circuit;
the first conductive connector is electrically connected to the negative terminal;
the plurality of the positive terminals are in one-to-one correspondence with the conductive plates, and each positive terminal of the plurality of the positive terminals is electrically connected to the corresponding conductive plate via a respective second conductive connector, and the second conductive connector abuts against at least one of the circuit board or the corresponding conductive plate.

16. The display apparatus according to claim 14, wherein the electrically debondable adhesive layer comprises a plurality of adhesive frames isolated from each other, the plurality of adhesive frames are in one-to-one correspondence with the conductive plates, and each adhesive frame of the plurality of adhesive frames is bonded and fixed to a peripheral edge of the corresponding conductive plate and is in electrical contact with the corresponding conductive plate;
the circuit board comprises a plurality of positive terminals and a plurality of negative terminals that are connected to a power circuit;
the display apparatus comprises a plurality of the conductive elements and a plurality of the first conductive connectors;
each adhesive frame of the plurality of adhesive frames is electrically connected to a respective independent conductive element, and each of the plurality of the first conductive connectors is electrically connected to a respective positive terminal;
the support frame is a metal frame, and the metal frame is electrically connected to the negative terminals.

17. The display apparatus according to claim 1, wherein a surface of the conductive element facing the circuit board is provided with a position-limiting groove, and the position-limiting groove is configured to accommodate an end portion of the first conductive connector facing away from the circuit board.

18. The display apparatus according to claim 1, wherein one end of the first conductive connector facing the circuit board is fixed to the circuit board, and one end of the first conductive connector facing the conductive element abuts against the conductive element.

19. The display apparatus according to claim 1, wherein the first conductive connector comprises a compressible portion.

20. An electronic device, comprising the display apparatus, wherein the display apparatus comprises:
a support frame, wherein the support frame comprises a first surface and a second surface opposite to each other;
a display module, wherein the display module is fixed to the first surface via an electrically debondable adhesive layer;
a circuit board, wherein the circuit board positioned on a side of the support frame facing away from the display module;
a conductive element, wherein the conductive element is positioned between the display module and the circuit board, and the conductive element is electrically connected to the electrically debondable adhesive layer; and
a first conductive connector, wherein the circuit board and the conductive element are electrically connected to each other via the first conductive connector, the first conductive connector abuts against at least one of the circuit board or the conductive element, and the circuit board is configured to provide a predetermined voltage for the electrically debondable adhesive layer via the first conductive connector.
